(19) United States
(12) Patent Application Publication
(10) Pub. No.: US 2024/0421093 A1
(43) Pub. Date: Dec. 19, 2024

(54) WIRING SUBSTRATE AND SEMICONDUCTOR PACKAGE INCLUDING THE SAME

(71) Applicant: Samsung Electronics Co., Ltd., Suwon-si (KR)

(72) Inventor: YOUNGBAE KIM, SUWON-SI (KR)

(21) Appl. No.: 18/419,469

(22) Filed: Jan. 22, 2024

(30) Foreign Application Priority Data
Jun. 13, 2023 (KR) 10-2023-0075823

(51) Int. Cl. H01L 23/538; H01L 23/00; H01L 23/31; H01L 23/498; H01L 25/065; H10B 80/00

(52) U.S. Cl. CPC H01L 23/5383; H01L 23/3128; H01L 23/49811; H01L 23/5384; H01L 24/16; H01L 24/32; H01L 24/73; H01L 25/0652; H01L 25/0657; H01L 2224/16227; H01L 2224/32225; H01L 2224/73204; H10B 80/00

(57) ABSTRACT

Embodiments of a wiring substrate is provided. Embodiments include a first redistribution layer, a first core layer disposed on the first redistribution layer, a second core layer disposed on the first core layer, a first adhesion layer disposed between the first core layer and the second core layer, and a second redistribution layer disposed on the second core layer. In some cases, the first core layer includes a first core section and a first core pad disposed on a top surface of the first core section, wherein the second core layer includes a second core section and a second core pad disposed on a bottom surface of the second core section. The first core layer and the second core layer are electrically connected to each other through the first core pad and the second core pad.

### CROSS-REFERENCE TO RELATED APPLICATION

This U.S. nonprovisional application claims priority under 35 U.S.C. § 119 to Korean Patent Application No. 10-2023-0075823, filed on Jun. 13, 2023, in the Korean Intellectual Property Office, the disclosure of which is incorporated by reference herein in its entirety.

### TECHNICAL FIELD

Embodiments of the present inventive concepts relate to a wiring substrate and a semiconductor package including the same.

### DISCUSSION OF RELATED ART

In recent times, as electronic products continue to advance in terms of high density and performance, there is an increasing demand for high reliability in circuit boards that are embedded in these electronic devices. These circuit boards consist of a stack of alternating wiring layers for circuit connections and dielectric layers for interlayer insulation. The wiring layers are primarily composed of metals, such as copper, while the dielectric layers are predominantly made of polymeric resins like resin or epoxy.

It is important for the dielectric layer to be thin to achieve circuit board that is not too thick, but reducing the thickness may lead to challenges in warpage control. For example, when compared to the wiring layer made of metals, adjusting characteristics of a low coefficient of thermal expansion (CTE), a high glass transition temperature (Tg), and a high modulus can be challenging, ultimately leading to a degradation in electrical, thermal, and mechanical properties.

Therefore, it is important to have a core with a low CTE and a high modulus to lessen warpage of the circuit board. Glass is a suitable candidate for satisfying such requirements.

Although the glass is processed in the form of a glass substrate, handling and processing the glass substrate is challenging, so there are difficulties in development.

### SUMMARY

Embodiments of the present inventive concepts provide a wiring substrate whose stiffness is increased, a semiconductor package including the same, and a method of fabricating the same.

Embodiments of the present inventive concepts provide a wiring substrate whose degree of freedom is increased, a semiconductor package including the same, and a method of fabricating the same.

Embodiments of a wiring substrate are provided. Embodiments include a first redistribution layer, a first core layer disposed on the first redistribution layer, a second core layer disposed on the first core layer, a first adhesion layer disposed between the first core layer and the second core layer, and a second redistribution layer disposed on the second core layer. In some cases, the first core layer includes a first core section, wherein the second core layer includes a second core section and a second core pad disposed on a bottom surface of the second core section. The first core layer and the second core layer are electrically connected to each other through the first core pad and the second core pad.

Embodiments of a wiring substrate are provided. Embodiments include a first redistribution layer, a second redistribution layer disposed on the first redistribution layer, a first core layer disposed between the first redistribution layer and the second redistribution layer, and a second core layer disposed between the first core layer and the second redistribution layer. In some embodiments, the first core layer includes a first core section, a first core pad disposed on a top surface of the first core section, and a first through via that vertically penetrates the first core section and is connected to the first core pad, wherein the second core layer includes a second core section, a second core pad disposed on a bottom surface of the second core section, and a second through via that vertically penetrates the second core section and is electrically connected to the second core pad. The first core layer and the second core layer are electrically connected to each other through the first core pad and the second core pad. The first through via and the second through via are moved away from each other.

Embodiments of a semiconductor package are provided. Embodiments include a wiring substrate, a semiconductor chip disposed on the wiring substrate, and a molding layer disposed on the wiring substrate while covering the semiconductor chip. In some embodiments, the wiring substrate includes a first redistribution layer, a first core layer, a second core layer, and a second redistribution layer that are sequentially stacked. The first core layer includes a first core section, and a first core pad disposed on a top surface of the first core section, wherein the second core layer includes a second core section, and a second core pad disposed on a bottom surface of the second core section. The first core pad and the second core pad are in direct contact with each other.

### BRIEF DESCRIPTION OF DRAWINGS

FIG. 1 is a cross-sectional view illustrating a wiring substrate according to some embodiments of the present inventive concepts.

FIGS. 2 to 6 are enlarged views illustrating a wiring substrate according to some embodiments of the present inventive concepts.

FIG. 7 is a cross-sectional view illustrating a wiring substrate according to some embodiments of the present inventive concepts.

FIGS. 8 and 9 are enlarged views illustrating a wiring substrate according to some embodiments of the present inventive concepts.

FIG. 10 is a cross-sectional view illustrating a wiring substrate according to some embodiments of the present inventive concepts.

FIGS. 11 and 12 are cross-sectional views illustrating a wiring substrate and a semiconductor package including the same according to some embodiments of the present inventive concepts.

FIGS. 13 to 19 are cross-sectional views illustrating a method of fabricating a wiring substrate according to some embodiments of the present inventive concepts.

### DETAILED DESCRIPTION OF EMBODIMENTS

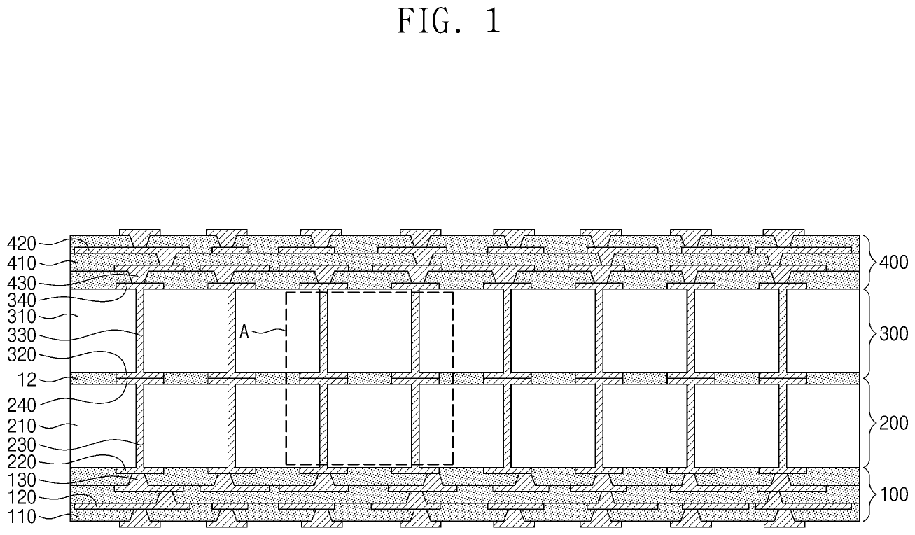

FIG. 1 is a cross-sectional view illustrating a semiconductor package according to some embodiments of the present inventive concepts.

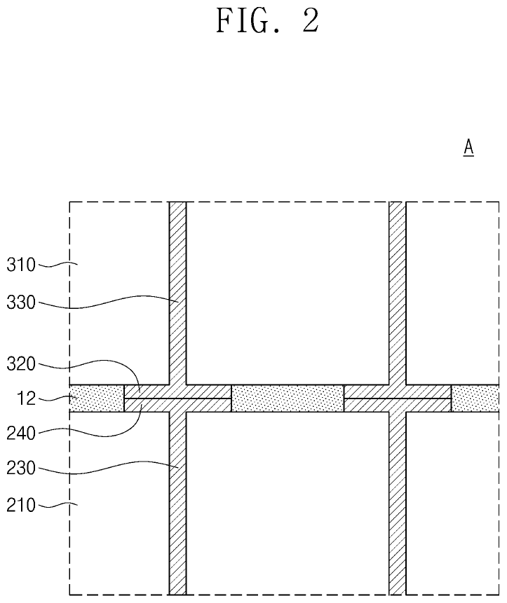

FIG. 2 is an enlarged view of section A depicted in FIG. 1, illustrating a wiring substrate according to some embodiments of the present inventive concepts.

Referring to FIGS. 1 and 2, a first redistribution layer 100 may be provided. The first redistribution layer 100 may include one or more substrate wiring layers that are stacked on each other. Each of the substrate wiring layers may include a first substrate dielectric pattern 110 and a first substrate wiring pattern 120 on the first substrate dielectric pattern 110. The first substrate wiring pattern 120 of one substrate wiring layer may be electrically connected to the first substrate wiring pattern 120 of an adjacent substrate wiring layer.

The first substrate dielectric pattern 110 may include a dielectric polymer or a photo-imageable dielectric (PID). For example, the PID may include photosensitive polyimide, polybenzoxazole (PBO), phenolic polymers, and/or benzocyclobutene polymers.

The first substrate wiring pattern 120 may be provided on the first substrate dielectric pattern 110. For example, the first substrate wiring pattern 120 may be provided on a bottom surface of the first substrate dielectric pattern 110. The first substrate wiring pattern 120 may protrude into the bottom surface of the first substrate dielectric pattern 110. The first substrate wiring pattern 120 may horizontally extend on the bottom surface of the first substrate dielectric pattern 110. For example, the first substrate wiring pattern 120 may be a pad or line part of the substrate wiring layer. The first substrate wiring pattern 120 may be a component for horizontal redistribution in the first redistribution layer 100. The first substrate wiring pattern 120 may include a conductive material. For example, the first substrate wiring pattern 120 may include copper (Cu).

A first substrate via 130 may be provided on the first substrate wiring pattern 120. The first substrate via 130 may be provided on a top surface of the first substrate wiring pattern 120. The first substrate via 130 may extend vertically and connect the first substrate wiring pattern 120 to neighboring substrate wiring layers. For example, the first substrate via 130 may vertically extend from the top surface of the first substrate wiring pattern 120 and pass through the first substrate dielectric pattern 110, thereby connecting a bottom surface of the first substrate wiring pattern 120 of an overlying substrate wiring layer. For another example, the first substrate via 130 may extend from the top surface of the first substrate wiring pattern 120 and pass through an uppermost first substrate dielectric pattern 110, thereby connecting to a first core pad 220.

A first core layer 200 may be provided on the first redistribution layer 100. In this configuration, an outer lateral surface of the first redistribution layer 100 may be aligned with that of the first core layer 200. The first core layer 200 may include a first core section 210, a first through via 230, a first core pad 220, and a second core pad 240.

The first core section 210 may have a plate shape. As used herein, the term “plate shape” refers to a three-dimensional structure with straight edges and right angles between its rectangular side faces. For example, a side view of the first core section 210 may be a rectangle. The first core section 210 may include a one or more core patterns in a plan view. The first core section 210 may include glass or a dielectric polymer.

The first core pad 220 may be provided on a bottom surface of the first core section 210. The first core pad 220 may be covered with the first substrate dielectric pattern 110. For example, the first substrate dielectric pattern 110 may be in direct contact with a lateral surface of the first core pad 220. The first substrate wiring pattern 120 disposed on a top surface of the first redistribution layer 100 may be coupled to a bottom surface of the first core pad 220. Therefore, the first core layer 200 may be electrically connected through the first core pad 220 to the first redistribution layer 100. The first core pad 220 may include a conductive material. For example, the first core pad 220 may include a metal such as copper (Cu). The first core layer 200 may include one or more first core pads 220.

The first through via 230 may vertically penetrate the first core section 210. The first through via 230 may extend to the bottom surface of the first core section 210 and contact one of the first core pads 220. The first through via 230 and the first core pad 220 may be integrally connected to constitute a single unitary piece. The first core layer 200 may include one or more first through vias 230.

The second core pad 240 may be provided on a top surface of the first core section 210. The second core pad 240 may be connected to one of the first through vias 230 that extend to the top surface of the first core section 210. The second core pad 240 and the first through via 230 may be integrally connected to constitute a single unitary piece. For example, FIG. 1 illustrates that the first through via 230, the first core pad 220, and the second core pad 240 are integrally connected to constitute a single unitary piece. However, the arrangement of the first through via 230, the first core pad 220, and the second core pad 240 illustrated in FIG. 1 is illustrative and are not necessarily limited thereto. 6ecFor example, the first through via 230, the first core pad 220, and the second core pad 240 may be separate and distinct components from each other. The second core pad 240 may include a conductive material. For example, the second core pad 240 may include a metal such as copper (Cu). The first core layer 200 may include one or more second core pads 240.

A second core layer 300 may be provided on the first core layer 200. The second core layer 300 may include a second core section 310, a second through via 330, a third core pad 320, and a fourth core pad 340.

The second core section 310 may have a plate shape. As used herein, the term “plate shape” refers to a three-dimensional structure with straight edges and right angles between its rectangular side faces. For example, a side view of the second core section 310 may be a rectangle. The second core section 310 may include a one or more core patterns in a plan view. The second core section 310 may include glass or a dielectric polymer.

The third core pad 320 may be provided on a bottom surface of the second core section 310. A bottom surface of the third core pad 320 may be in contact with a top surface of the second core pad 240. For example, a visible interface may be formed between the second core pad 240 and the third core pad 320. The second core layer 300 may be electrically connected through the third core pad 320 to the first core layer 200. The third core pad 320 may include a conductive material. For example, the third core pad 320 may include a metal such as copper (Cu). The second core layer 300 may include one or more third core pads 340.

The second through via 330 may vertically penetrate the second core section 310. The second through via 330 may extend to the bottom surface of the second core section 310 and contact one of the third core pads 320. The second through via 330 and the third core pad 320 may be integrally connected to constitute a single unitary piece. The second core layer 300 may include one or more second through vias 330.

The fourth core pad 340 may be provided on a top surface of the second core section 310. The fourth core pad 340 may be connected to one of the second through vias 330 that extend to the top surface of the second core section 310. The fourth core pad 340 and the second through via 330 may be integrally connected to constitute a single unitary piece. The second through via 330 may be electrically connected to the fourth core pad 340. For example, FIG. 1 illustrates that the second through via 330, the third core pad 320, and the fourth core pad 340 are integrally connected to constitute a single unitary piece. However, the arrangement of the second through via 330, the third core pad 220, and the fourth core pad 240 illustrated in FIG. 1 is illustrative and are not necessarily limited thereto. For example, the second through via 330, the third core pad 320, and the fourth core pad 340 may be separate and distinct components from each other. The fourth core pad 340 may include a conductive material. For example, the fourth core pad 340 may include a metal such as copper (Cu). The second redistribution layer 400 may include one or more fourth core pads 340.

The first through via 230 and the second through via 330 may be vertically aligned with each other. The second core pad 240 may have a planar shape substantially the same as or similar to that of the third core pad 320. For example, a width of the second core pad 240 may be the same as that of the third core pad 320. The width of each of the second and third core pads 240 and 320 may be a width measured in a direction parallel to the top surface of the first redistribution layer 100. The second core pad 240 may have an outer lateral surface aligned with that of the third core pad 320. The second core pad 240 and the third core pad 320 may overlap each other.

A first adhesion layer 12 may be provided between the first core layer 200 and the second core layer 300. For example, the first core layer 200 and the second core layer 300 may be attached to each other by the first adhesion layer 12. The first adhesion layer 12 may fill a space between the first core layer 200 and the second core layer 300 and may at least partially surround the second core pad 240 and the third core pad 320. The first adhesion layer 12 may include a die attach adhesive (DAA).

A second redistribution layer 400 may be provided on the second core layer 300. The second redistribution layer 400 may include one or more substrate wiring layers that are stacked on each other. Each of the substrate wiring layers may include a second substrate dielectric pattern 410 and a second substrate wiring pattern 420 on the second substrate dielectric pattern 410. The second substrate wiring pattern 420 of a substrate wiring layer may be electrically connected to the second substrate wiring pattern 420 of an adjacent substrate wiring layer.

The second substrate dielectric pattern 410 may include a dielectric polymer or a photo-imageable dielectric (PID). For example, the photo-imageable dielectric may include photosensitive polyimide, polybenzoxazole (PBO), phenolic polymers, and/or benzocyclobutene polymers. The fourth core pad 340 may be covered with the second substrate dielectric pattern 410 of a lowermost substrate wiring layer. For example, the second substrate dielectric pattern 410 may be in direct contact with a lateral surface of the fourth core pad 340.

The second substrate wiring pattern 420 may be provided on the second substrate dielectric pattern 410. For example, the second substrate wiring pattern 420 may be provided on a top surface of the second substrate dielectric pattern 410. The second substrate wiring patterns 420 may protrude into the top surface of the second substrate dielectric pattern 410. The second substrate wiring pattern 420 may horizontally extend on the top surface of the second substrate dielectric pattern 410. For example, the second substrate wiring pattern 420 may be a pad or line part of the substrate wiring layer. The second substrate wiring pattern 420 may be a component for horizontal redistribution in the second redistribution layer 400. The second substrate wiring pattern 420 may include a conductive material. For example, the second substrate wiring pattern 420 may include copper (Cu). The second substrate wiring pattern 420 of an uppermost substrate wiring layer may be exposed on a top surface of the second redistribution layer 400. The exposed second substrate wiring pattern 420 may serve as a pad on which an external package or an electronic device is mounted.

A second substrate via 430 may be provided on the second substrate wiring pattern 420. The second substrate via 430 may be provided on a bottom surface of the second substrate wiring pattern 420. The second substrate via 430 may extend vertically and connect of the second substrate wiring patterns 420 of neighboring substrate wiring layers. For example, the second substrate via 430 may extend from the bottom surface of the second substrate wiring pattern 420 and pass through the second substrate dielectric pattern 410, thereby connecting a top surface of the second substrate wiring pattern 420 of an underlying another substrate wiring layer. For another example, the second substrate via 430 may extend from the bottom surface of the second substrate wiring pattern 420 and pass through a lowermost second substrate dielectric pattern 410, thereby connecting a top surface of the fourth core pad 340.

A wiring substrate may be provided as discussed above. According to some embodiments of the present inventive concepts, a plurality of core layers may be provided between redistribution layers, and thus a wiring substrate may have increased stiffness.

To the extent that an element has not been described in detail herein, it may be assumed that the element is at least similar to corresponding elements that have been described elsewhere within the present disclosure. The same numerals will be allocated to the same components of the wiring substrate discussed above according to some embodiments of the present inventive concepts.

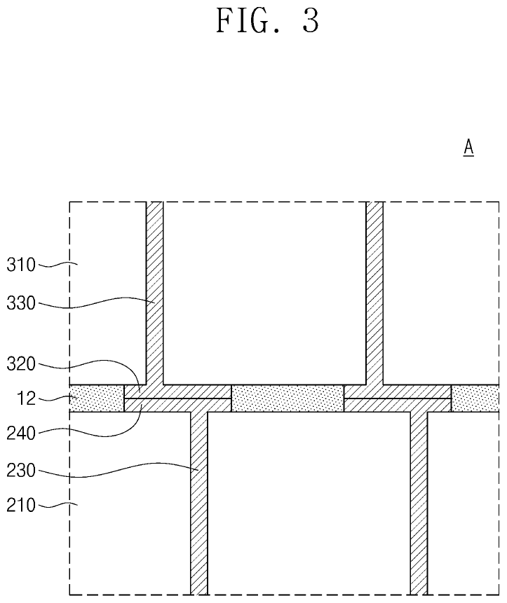

FIG. 3 is an enlarged view of section A depicted in FIG. 1, illustrating a wiring substrate according to some embodiments of the present inventive concepts.

Referring to FIG. 3, the first through via 230 and the second through via 330 may be horizontally moved away from one another. In a plan view, the first through via 230 may be positioned on a side of the second through via 330. For example, the first through via 230 and the second through via 330 might not overlap each other. The first core layer 200 may be electrically connected to the second core layer 300 through the first through via 230, the second core pad 240, the third core pad 320, and the second through via 330. The second core pad 240 and the third core pad 320 may overlap each other.

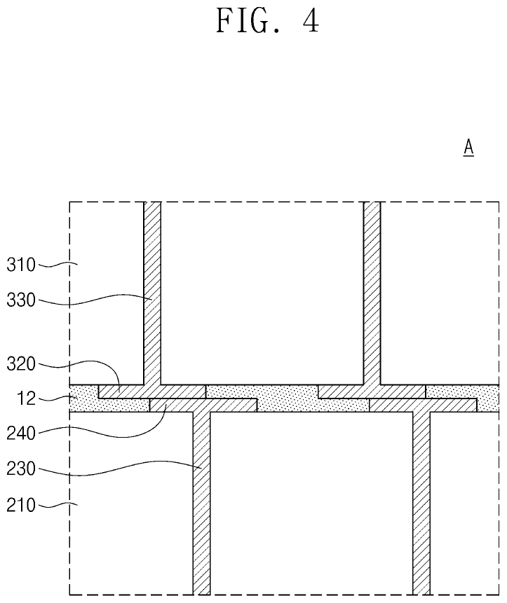

FIG. 4 is an enlarged view of section A depicted in FIG. 1, illustrating a wiring substrate according to some embodiments of the present inventive concepts.

Referring to FIG. 4, the first through via 230 and the second through via 330 may be moved away from each other along a direction that parallels the top surface of the first redistribution layer 100. The second core pad 240 and the third core pad 320 may be moved away from one another along a direction that runs parallel to the top surface of the first redistribution layer 100. For example, a portion of the top surface of the second core pad 240 may overlap a portion of the bottom surface of the third core pad 320 while other areas of the top surface of the second core pad 240 might not contact the third core pad 320.

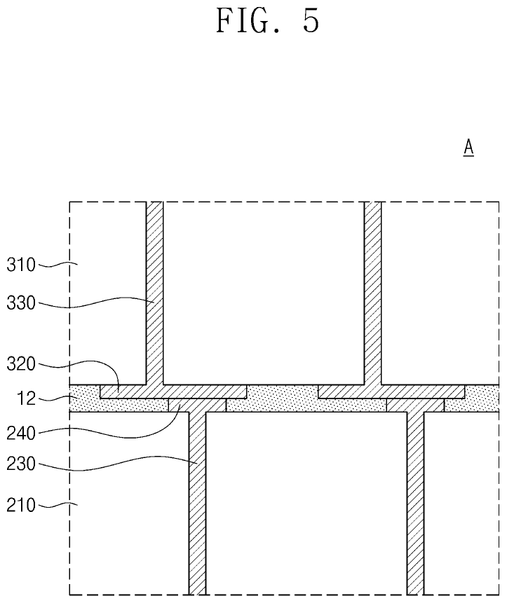

FIG. 5 is an enlarged view of section A depicted in FIG. 1, illustrating a wiring substrate according to some embodiments of the present inventive concepts.

Referring to FIG. 5, the first through via 230 and the second through via 330 may be moved away from each other along a direction that parallels the bottom surface of the second redistribution layer 400. The second core pad 240 may have a width different from that of the third core pad 320. For example, the third core pad 320 may horizontally extend onto the first through via 230 to contact the second core pad 240. Accordingly, the third core pad 320 may overlap both the first through via 230 and the second through via 330. The second core pad 240 may overlap only the first through via 230 and might not overlap the second through via 330.

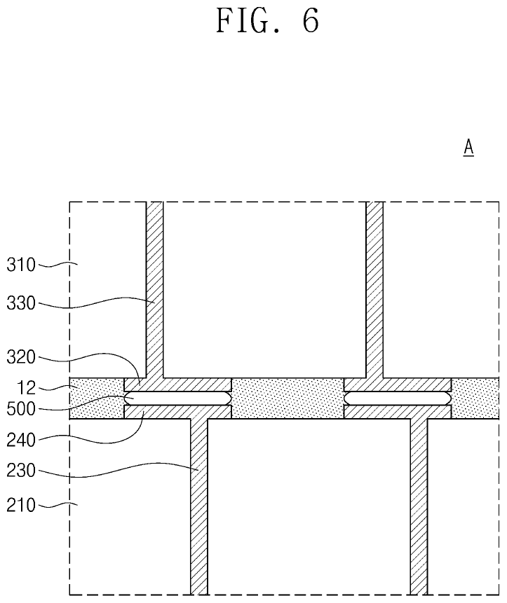

FIG. 6 is an enlarged view of section A depicted in FIG. 1, illustrating a wiring substrate according to some embodiments of the present inventive concepts.

Referring to FIG. 6, the wiring substrate may further include a first connection terminal 500 between the second core pad 240 and the third core pad 320. The first connection terminal 500 may be in contact with the top surface of the second core pad 240 and the bottom surface of the third core pad 320. The first adhesion layer 12 may at least partially surround the second core pad 240, the third core pad 320, and the first connection terminal 500. The first connection terminal 500 may include a conductive material. For example, the first connection terminal 500 may be a solder bump. The present inventive concepts, however, are not necessarily limited thereto. In some cases, for example, the first connection terminal 500 may be a conductive pad formed of copper (Cu). There may be one or more first connection terminals 500.

In some embodiments, the first through via 230 and the second through via 330 may be horizontally moved away from one another. Thus, it may be possible to increase the degree of wiring freedom in each core layer and provide a strong electrical connection between the first core layer 200 and the second core layer 300. Accordingly, the wiring substrate may be provided with a high degree of wiring freedom.

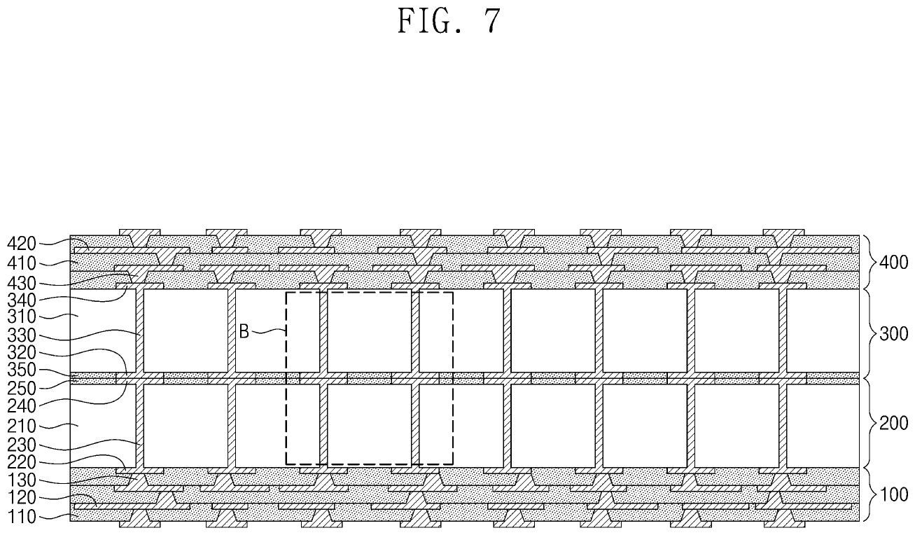

FIG. 7 is a cross-sectional view illustrating a wiring substrate according to some embodiments of the present inventive concepts.

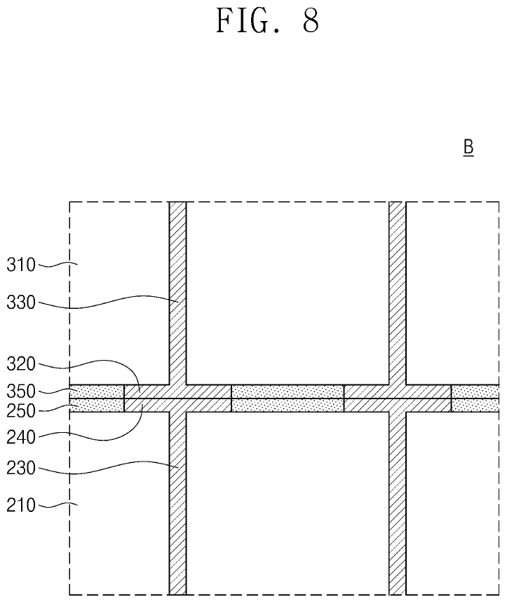

FIG. 8 is an enlarged view of section B depicted in FIG. 7, illustrating a wiring substrate according to some embodiments of the present inventive concepts.

Referring to FIGS. 7 and 8, the first core layer 200 may further include a first dielectric layer 250 on the top surface of the first core section 210. The first dielectric layer 250 may at least partially surround the second core pad 240. The first dielectric layer 250 may cover the top surface of the first core section 210 while exposing the second core pad 240. The first dielectric layer 250 may have a top surface substantially coplanar with that of the second core pad 240. The first dielectric layer 250 may include a dielectric material. For example, the first dielectric layer 250 may include silicon nitride (SiN), silicon oxide (SiO), silicon oxynitride (SiON), or tetraethylorthosilicate (TEOS).

The second core layer 300 may further include a second dielectric layer 350 on the bottom surface of the second core section 310. The second dielectric layer 350 may at least partially surround the third core pad 320. The second dielectric layer 350 may cover the bottom surface of the second core section 310 while exposing the third core pad 320. The second dielectric layer 350 may have a bottom surface substantially coplanar with that of the third core pad 320. The second dielectric layer 350 may include a dielectric material. For example, the second dielectric layer 350 may include silicon nitride (SiN), silicon oxide (SiO), silicon oxynitride (SiON), or tetraethylorthosilicate (TEOS).

The second core layer 300 may be disposed on the first core layer 200. For example, the second core layer 300 may be disposed so that its bottom surface face a top surface of the first core layer 200. The first core layer 200 and the second core layer 300 may be in contact with each other. For example, the top surface of the first dielectric layer 250 may be in contact with the bottom surface of the second dielectric layer 350. In addition, the second core pad 240 on the top surface of the first core layer 200 may be in direct contact with the third core pad 320 on the bottom surface of the second core layer 300. The second core pad 240 and the third core pad 320 may constitute an intermetallic hybrid bonding. The term “hybrid bonding” refers to a bonding in which two components of the same kind are merged at an interface therebetween. For example, the second core pad 240 and the third core pad 320 bonded to each other may have a continuous configuration, and an invisible interface may be present between the second core pad 240 and the third core pad 320. In some embodiments, the second core pad 240 and the third core pad 320 may be formed of the same material, and without the interface between them. For example, the second core pad 240 and the third core pad 320 may be a integrally connected to constitute a single unitary piece. The present inventive concepts, however, are not necessarily limited thereto. According to some embodiments, the second core pad 240 and the third core pad 320 may have separate and distinct configurations from each other and may have a visible interface therebetween. The first core layer 200 may be electrically connected through the second core pad 240 to the second core layer 300.

The first through via 230 and the second through via 330 may be vertically aligned with each other. The second core pad 240 may have a planar shape substantially the same as or similar to that of the third core pad 320. For example, a width of the second core pad 240 may be the same as that of the third core pad 320. The second core pad 240 and the third core pad 320 may be vertically aligned with each other. The second core pad 240 may have an outer lateral surface aligned with that of the third core pad 320. The second core pad 240 and the third core pad 320 may overlap each other. The present inventive concepts, however, are not necessarily limited thereto. Alternatively, the first through via 230 and the second through via 330 may be moved away from each other along a direction that parallels the top surface of the second redistribution layer 400. Additionally, in some embodiments, the second core pad 240 and the third core pad 320 may have different widths from each other, and may be moved away from each other. Thus, it may be possible to increase the degree of wiring freedom in each core layer and provide a strong electrical connection between the first core layer 200 and the second core layer 300. Accordingly, the wiring substrate may be provided with a high degree of wiring freedom.

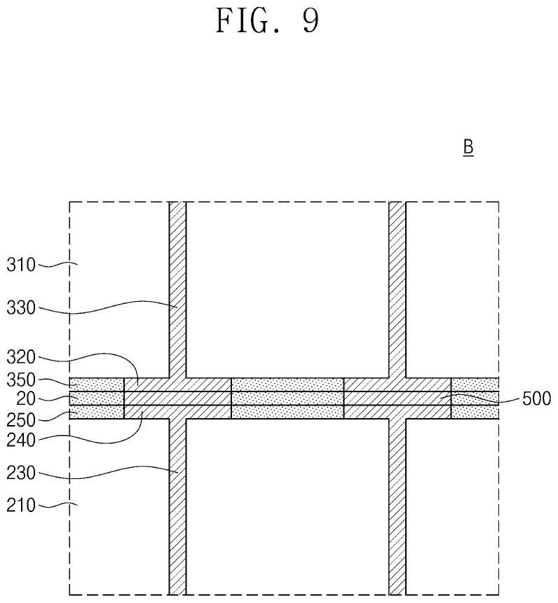

FIG. 9 is an enlarged view of section B depicted in FIG. 7, illustrating a wiring substrate according to some embodiments of the present inventive concepts.

Referring to FIG. 9, the wiring substrate may further include a first connection terminal 500 between the second core pad 240 and the third core pad 320, and may also further include a third dielectric layer 20 including the first connection terminal 500. The third dielectric layer 20 may be in contact with the first core layer 200 and the second core layer 300. For example, a top surface of the second core pad 240 may be in contact with a bottom surface of the first connection terminal 500. A bottom surface of the third core pad 320 may be in contact with a top surface of the first connection terminal 500. The second core pad 240, the third core pad 320, and the first connection terminal 500 may have their outer lateral surfaces that are aligned with each other. The first connection terminal 500 may include a conductive material. For example, the first connection terminal 500 may be a conductive pad formed of copper (Cu). The present inventive concepts, however, are not necessarily limited thereto. For another example, the first connection terminal 500 may be a solder bump.

According to some embodiments of the present inventive concepts, the first through via 230 and the second through via 330 may be vertically aligned with each other. The present inventive concepts, however, are not necessarily limited thereto. In some cases, for example, the first through via 230 and the second through via 330 may be moved away from each other. Thus, it may be possible to increase the degree of wiring freedom in each core layer and provide a strong electrical connection between the first core layer 200 and the second core layer 300. Accordingly, the wiring substrate may be provided with a high degree of wiring freedom.

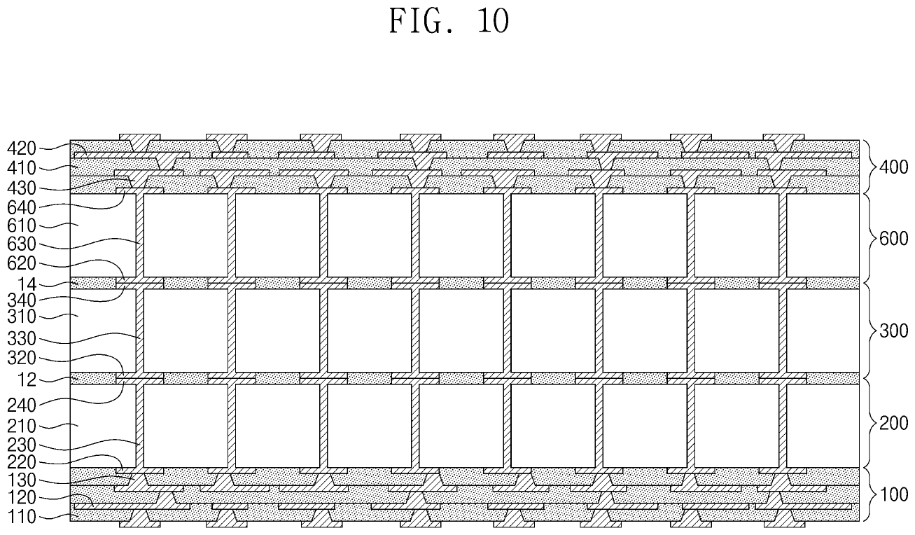

FIG. 10 is a cross-sectional view illustrating a wiring substrate according to some embodiments of the present inventive concepts.

Referring to FIG. 10, the wiring substrate may further include a third core layer 600 between the second core layer 300 and the second redistribution layer 400. The third core layer 600 may be disposed on a top surface of the second core layer 300. The third core layer 600 may include a third core section 610, a third through via 630, a fifth core pad 620, and a sixth core pad 640.

The third core section 610 may have a plate shape. As used herein, the term “plate shape” refers to a three-dimensional structure with straight edges and right angles between its rectangular side faces. For example, a side view of the third core section 610 may be a rectangle. The third core section 610 may include a single or plurality of core patterns in a plan view. The third core section 610 may include glass or a dielectric polymer.

The fifth core pad 620 may be provided on a bottom surface of the third core section 610. The bottom surface of the fifth core pad 620 may be in contact with the top surface of the fourth core pad 340. For example, the fourth core pad 340 and the fifth core pad 620 may have the same width and may have a visible interface therebetween. The third core layer 600 may be electrically connected through the fifth core pad 620 to the second core layer 300. The fifth core pad 620 may include a conductive material. For example, the fifth core pad 620 may include a metal such as copper (Cu). The fifth core pad 620 may be provided in plural.

The third through via 630 may vertically penetrate the third core section 610. The third through via 630 may extend to the bottom surface of the third core section 610 and contact one of the fifth core pads 620. The third through via 630 and the fifth core pad 620 may be integrally connected to constitute a single unitary piece. The third through via 630 may be vertically aligned with the first through via 230 and the second through via 330. The third core layer 600 may include one or more third through vias 630.

The sixth core pad 640 may be provided on a top surface of the third core section 610. The sixth core pad 640 may be connected to one of the third through vias 630. The sixth core pad 640 and the third through via 630 may be integrally connected to constitute a single unitary piece. The third through via 630 may be electrically connected to the sixth core pad 640. For example, FIG. 10 illustrates that the third through via 630, the fifth core pad 620, and the sixth core pad 640 are integrally connected to constitute a single unitary piece. However, the arrangement of the third through via 630, the fifth core pad 620, and the sixth core pad 640 illustrated in FIG. 10 is illustrative and are not necessarily limited thereto. For example, the third through via 630, the fifth core pad 620, and the sixth core pad 640 may be separate and distinct components from each other. The sixth core pad 640 may include a conductive material. For example, the sixth core pad 640 may include a metal such as copper (Cu). There may be one or more sixth core pads 640.

A second adhesion layer 14 may be provided between the second core layer 300 and the third core layer 600. For example, the second core layer 300 and the third core layer 600 may be attached to each other by the second adhesion layer 14. The second adhesion layer 14 may at least partially surround the fourth core pad 340 and the fifth core pad 620. The second adhesion layer 14 may include a die attach adhesive (DAA).

The wiring substrate may be provided as discussed above. According to some embodiments of the present inventive concepts, a plurality of core layers may be provided between redistribution layers, and thus the wiring substrate may have increased stiffness.

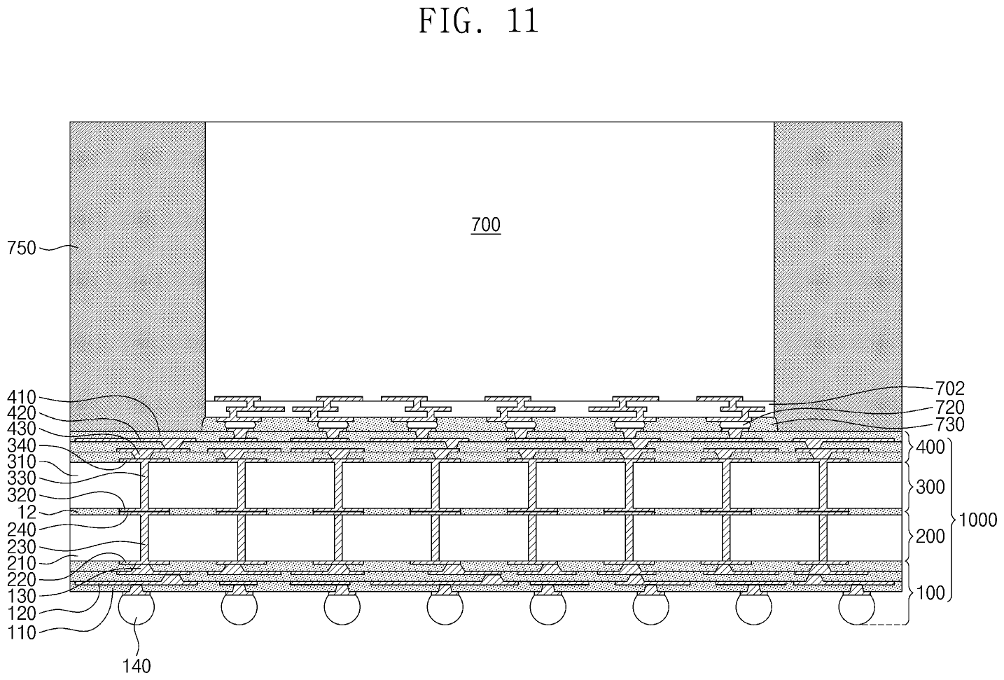

FIG. 11 is a cross-sectional view illustrating a wiring substrate and a semiconductor package including the same according to some embodiments of the present inventive concepts.

Referring to FIG. 11, a wiring substrate 1000 may be provided. The wiring substrate 1000 may include a first redistribution layer 100, a first core layer 200, a second core layer 300, and a second redistribution layer 400.

The first redistribution layer 100 may be provided with external terminals 140 disposed thereunder. For example, the external terminals 140 may be disposed on a bottom surface of a first substrate wiring pattern 120, thereby being visible from a bottom surface of the first redistribution layer 100. The external terminals 140 may include solder balls or solder bumps. Depending on a type of the external terminals 140, a semiconductor package 10 may be provided in the form of a ball grid array (BGA) type, a fine ball-grid array (FBGA) type, or a land grid array (LGA) type.

A first semiconductor chip 700 may be provided on the second redistribution layer 400. The first semiconductor chip 700 may include a semiconductor substrate. For example, the semiconductor substrate may include silicon (Si). The first semiconductor chip 700 may include a first circuit layer 702 on a bottom of the semiconductor substrate. The first circuit layer 702 may include a logic circuit. For example, the first semiconductor chip 700 may be a logic chip. Alternatively, the first circuit layer 702 may include a memory circuit. For example, the first semiconductor chip 700 may be a memory chip, such as a dynamic random access memory (DRAM), a static random access memory (SRAM), a magnetic random access memory (MRAM), or a Flash memory. A bottom surface of the first semiconductor chip 700 may be an active surface and a top surface of the first semiconductor chip 700 may be an inactive surface.

The first semiconductor chip 700 may be mounted on the second redistribution layer 400. For example, the first semiconductor chip 700 may be connected to a second substrate wiring pattern 420, which is exposed on a top surface of the second redistribution layer 400, by a second connection terminal 720. The second connection terminal 720 may be provided between the second substrate wiring pattern 420 and the first circuit layer 702 of the first semiconductor chip 700. As the first semiconductor chip 700 is mounted through the second connection terminal 720 on the second redistribution layer 400, the bottom surface of the first semiconductor chip 700 may be spaced apart from the second redistribution layer 400. The second redistribution layer 400 may include one or more second connection terminals 720.

A first underfill layer 730 may be provided between the second redistribution layer 400 and the first semiconductor chip 700. The first underfill layer 730 may at least partially surround the second connection terminals 720, while filling a space between the second redistribution layer 400 and the first semiconductor chip 700.

A first molding layer 750 may be disposed on the top surface of the second redistribution layer 400. The first molding layer 750 may at least partially surround the first semiconductor chip 700 and the first underfill layer 730. The first molding layer 750 may have a top surface coplanar with that of the first semiconductor chip 700. The first semiconductor chip 700 may be exposed on the top surface of the first molding layer 750. The first molding layer 750 may include a dielectric polymer material. For example, the first molding layer 750 may include an epoxy molding compound (EMC).

FIG. 11 depicts that a semiconductor chip is mounted on a wiring substrate, but the present inventive concepts are not necessarily limited thereto. In some embodiments, the wiring substrate may be provided thereon with a semiconductor package that includes a semiconductor chip and a chip stack including two or more semiconductor chips.

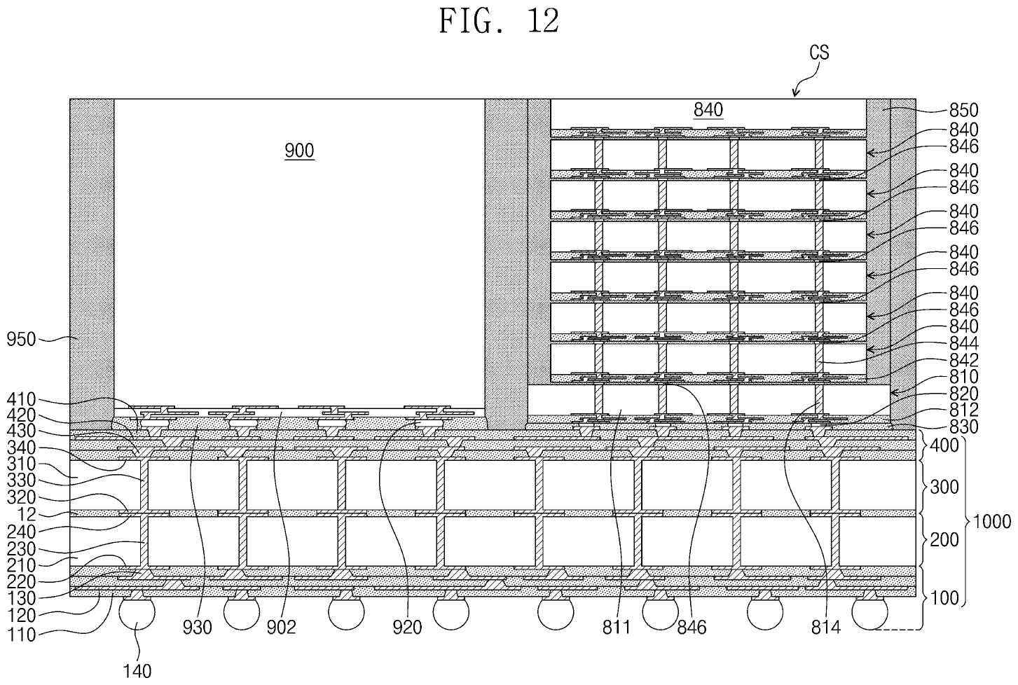

FIG. 12 is a cross-sectional view illustrating a wiring substrate and a semiconductor package including the same according to some embodiments of the present inventive concepts.

Referring to FIG. 12, a chip stack CS may be disposed on the wiring substrate 1000. The chip stack CS may include a base semiconductor chip 810, second semiconductor chips 840 stacked on the base semiconductor chip 810, and a second molding layer 850 that at least partially surrounds the second semiconductor chips 840.

The base semiconductor chip 810 may include a base semiconductor substrate 811. The base semiconductor substrate 811 may be a semiconductor substrate. For example, the base semiconductor substrate 811 may be a wafer-level semiconductor substrate formed of a semiconductor material, such as silicon (Si). A bottom surface of the base semiconductor chip 810 may be an active surface. For example, an integrated device or integrated circuits may be formed on a bottom surface of the base semiconductor substrate 811.

The base semiconductor chip 810 may include a base circuit layer 812 and a base through via 814. The base circuit layer 812 may be provided on the bottom surface of the base semiconductor chip 810. The base circuit layer 812 may include the integrated device or the integrated circuits. For example, the base circuit layer 812 may be a memory circuit and the base semiconductor chip 810 may be a memory chip, such as a dynamic random access memory (DRAM), a static random access memory (SRAM), a magnetic random access memory (MRAM), or a Flash memory. The base through via 814 may vertically penetrate the base semiconductor chip 810. The base through via 814 and the base circuit layer 812 may be electrically connected to each other.

The base semiconductor chip 810 may further include a protection layer and a third connection terminal 820. The protection layer may be disposed on the bottom surface of the base semiconductor chip 810, thereby covering the base circuit layer 812. The protection layer may include silicon oxide (SiO) or silicon nitride (SIN). The third connection terminal 820 may be provided on the bottom surface of the base semiconductor chip 810. The third connection terminal 820 may be electrically connected to an input/output circuit, a power circuit, or a ground circuit of the base circuit layer 812. There may be one or more third connection terminals 820.

A second underfill layer 830 may be provided between the second redistribution layer 400 and the chip stack CS. The second underfill layer 830 may at least partially surround the third connection terminals 820, while filling a space between the second redistribution layer 400 and the base semiconductor chip 810.

A second semiconductor chip 840 may be provided on the base semiconductor chip 810. The second semiconductor chip 840 may have a narrower width than that of the base semiconductor chip 810. The second semiconductor chip 840 may include a second circuit layer 842 and a fourth through via 844. The second circuit layer 842 may include a memory circuit. For example, the second semiconductor chip 840 may be a memory chip, such as a dynamic random access memory (DRAM), a static random access memory (SRAM), a magnetic random access memory (MRAM), or a Flash memory. The fourth through via 844 may vertically penetrate the second semiconductor chip 840. The fourth through electrode 844 and the second circuit layer 842 may be electrically connected to each other. A bottom surface of the second semiconductor chip 840 may be an active surface. The second semiconductor chip 840 may include connection bumps 846 on the bottom surface thereof. The connection bumps 846 may be disposed between the base semiconductor chip 810 and the second semiconductor chip 840, establishing an electrical connection between the two.

There may be one or more second semiconductor chips 840. For example, a plurality of second semiconductor chips 840 may be stacked on the base semiconductor chip 810. The number of stacked second semiconductor chips 840 may range from 8 to 32. The connection bumps 846 may be correspondingly provided between the second semiconductor chips 840. An uppermost second semiconductor chip 840 might not include the fourth through via 844. In addition, the uppermost second semiconductor chip 840 may have a thickness greater than those of other second semiconductor chips 840 disposed thereunder.

An adhesion layer may be provided between the second semiconductor chips 840. The adhesion layer may include a non-conductive film (NCF). The adhesion layer may be interposed between the connection bumps 846 among the second semiconductor chips 840 to prevent the occurrence of electrical short between the connection bumps 846.

The second molding layer 850 may be disposed on a top surface of the base semiconductor chip 810. The second molding layer 850 may partially cover the base semiconductor chip 810 and at least partially surround the second semiconductor chips 840. The second molding layer 850 may have a top surface coplanar with that of the uppermost second semiconductor chip 840. The uppermost second semiconductor chip 840 may be exposed on the top surface of the second molding layer 850. The second molding layer 850 may include a dielectric polymer material. For example, the second molding layer 850 may include an epoxy molding compound (EMC).

The chip stack CS may be mounted on the second redistribution layer 400. For example, the chip stack CS may be connected to the second substrate wiring pattern 420, which is disposed on the top surface of the second redistribution layer 400, by the third connection terminal 820. The third connection terminal 820 may be in contact with a top surface of the second substrate wiring pattern 420 and a bottom surface of the base circuit layer 812, and thus the chip stack CS and the second redistribution layer 400 may be electrically connected to each other.

A third semiconductor chip 900 may be provided on the wiring substrate 1000. The third semiconductor chip 900 may be horizontally spaced apart from the chip stack CS. The third semiconductor chip 900 may include a semiconductor material, such as silicon (Si). The third semiconductor chip 900 may further include a third circuit layer 902. The third circuit layer 902 may include a logic circuit. For example, the third semiconductor chip 900 may be a logic chip. A bottom surface of the third semiconductor chip 900 may be an active surface and a top surface of the third semiconductor chip 900 may be an inactive surface.

The third semiconductor chip 900 may be mounted on the second redistribution layer 400. For example, the third semiconductor chip 900 may be connected to the second substrate wiring pattern 420, which is disposed on the top surface of the second redistribution layer 400, by a fourth connection terminal 920. The fourth connection terminal 920 may be in contact with a top surface of the second substrate wiring pattern 420 and a bottom surface of the third circuit layer 902, and thus the third semiconductor chip 900 and the second redistribution layer 400 may be electrically connected to each other. There may be one or more fourth connection terminals 920.

A third underfill layer 930 may be provided between the second redistribution layer 400 and the third semiconductor chip 900. The third underfill layer 930 may at least partially surround the fourth connection terminals 920, while filling a space between the second redistribution layer 400 and the third semiconductor chip 900.

A third molding layer 950 may be disposed on the top surface of the second redistribution layer 400. The third molding layer 950 may at least partially surround the chip stack CS, the second underfill layer 830, the third semiconductor chip 900, and the third underfill layer 930. The third molding layer 950 may have a top surface coplanar with that of the third semiconductor chip 900 and that of the uppermost second semiconductor chip 840 in the chip stack CS, and the third semiconductor chip 900 and the second semiconductor chip 840 may be exposed on the top surface of the third molding layer 950. The third molding layer 950 may include a dielectric polymer material. For example, the third molding layer 950 may include an epoxy molding compound (EMC).

The present inventive concepts, however, are not necessarily limited thereto. FIG. 12 depicts that the third semiconductor chip 900 is mounted, but a dummy structure may be additionally disposed, and a chip structure may be mounted.

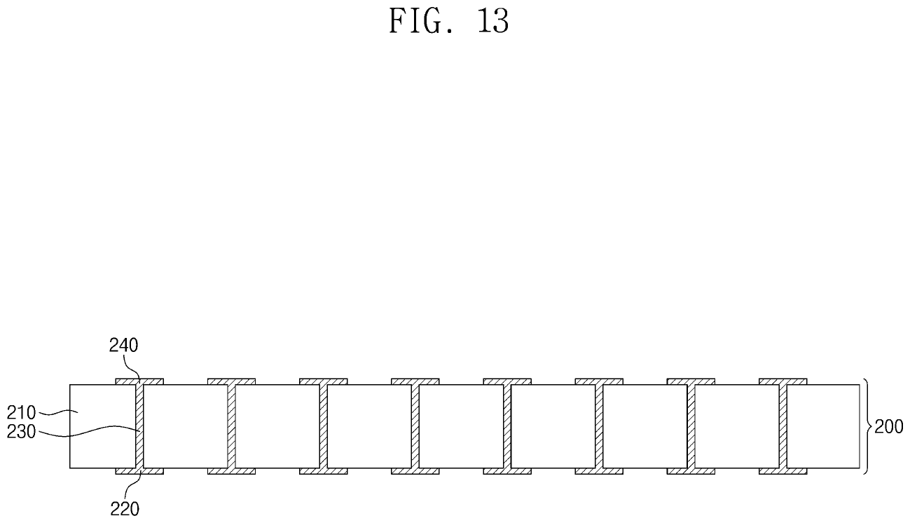

FIGS. 13 to 19 are cross-sectional views illustrating a method of fabricating a wiring substrate according to some embodiments of the present inventive concepts.

Referring to FIG. 13, a first core section 210 may be provided. The first core section 210 may undergo a photolithography process or an etching process to form through holes that penetrate the first core section 210. A conductive material may be coated on top and bottom surfaces of the first core section 210, and the through holes may be filled with a conductive material to form first through vias 230. A portion of the conductive material may cover the top and bottom surfaces of the first core section 210. The conductive material coated on the top and bottom surfaces of the first core section 210 may be selectively etched to form a first core pad 220 and a second core pad 240. The first core pad 220 may be formed on the bottom surface of the first core section 210, and the second core pad 240 may be formed on the top surface of the first core section 210. The method mentioned above may form a first core layer 200.

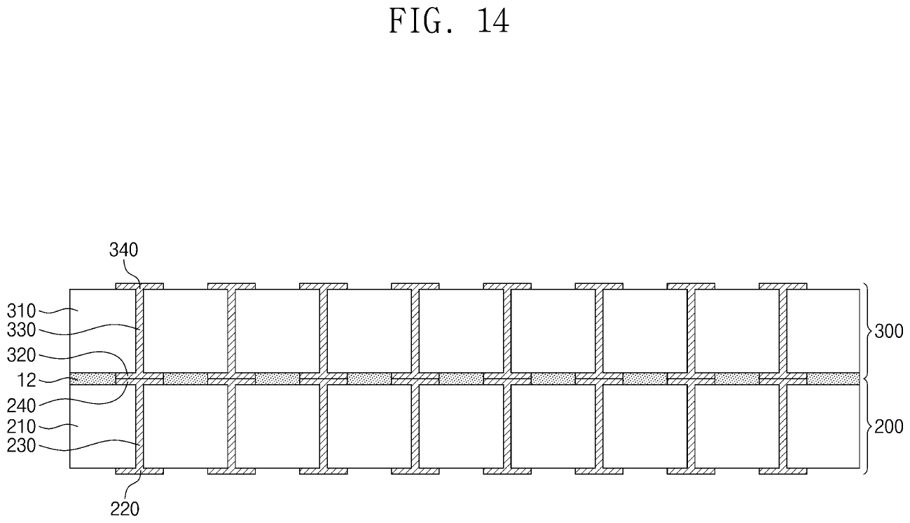

Referring to FIG. 14, a second core layer 300 may be provided. The second core layer 300 may be formed by substantially the same or similar method used for forming the first core layer 200 discussed above in FIG. 13.

The second core layer 300 may be disposed on the first core layer 200. The second core layer 300 may be aligned onto the first core layer 200 so as to allow a top surface of the second core pad 240 to contact a bottom surface of the third core pad 320. The first core layer 200 and the second core layer 300 may be attached through a first adhesion layer 12. For example, an adhesive may be coated between the top surface of the first core section 210 and a bottom surface of a second core section 310. The adhesive may bond the first core layer 200 and the second core layer 300 together. The adhesive may be in contact with the top surface of the first core section 210 and the bottom surface of the second core section 310. The adhesive may include a die attach film (DAF).

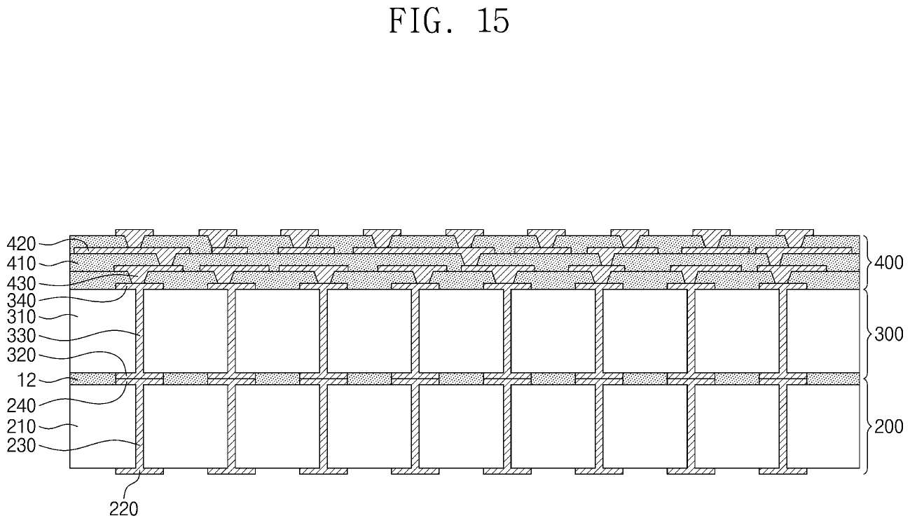

Referring to FIG. 15, a second redistribution layer 400 may be formed on the second core layer 300. A second substrate dielectric pattern 410 may be formed by coating a dielectric material on a top surface of the second core section 310. The second substrate dielectric pattern 410 may cover a fourth core pad 340 which is disposed on the top surface of the second core section 310. The second substrate dielectric pattern 410 may be patterned to form an opening that exposes the fourth core pad 340. A conductive layer may be formed on the second substrate dielectric pattern 410 to cover the second substrate dielectric pattern 410 and to fill the opening, and then the conductive layer may be patterned to form a second substrate wiring pattern 420 and a second substrate via 430. One substrate wiring layer may include the second substrate dielectric pattern 410, the second substrate wiring pattern 420 formed on the second substrate dielectric pattern 410, and the second substrate via 430. The process of forming the substrate wiring layer may be repeated to form the second redistribution layer 400.

Referring back to FIG. 1, a first redistribution layer 100 may be formed on a bottom surface of the first core layer 200. A first substrate dielectric pattern 110 may be formed by coating a dielectric material on the bottom surface of the first core section 210. The first substrate dielectric pattern 110 may cover the first core pad 220 disposed on the bottom surface of the first core section 210. The first substrate dielectric pattern 110 may be patterned to form an opening that exposes the first core pad 220. A conductive layer may be formed on the first substrate dielectric pattern 110 to cover the first substrate dielectric pattern 110 and to fill the opening, and then the conductive layer may be patterned to form a first substrate wiring pattern 120 and a first substrate via 130. A substrate wiring layer may include the first substrate dielectric pattern 110, the first substrate wiring pattern 120 formed on the first substrate dielectric pattern 110, and the first substrate via 130. The process of forming the substrate wiring layer may be repeated to form a first redistribution layer 100.

To the extent that an element has not been described in detail herein, it may be assumed that the element is at least similar to corresponding elements that have been described elsewhere within the present disclosure. The same numerals will be allocated to the same components of the wiring substrate discussed above according to some embodiments of the present inventive concepts.

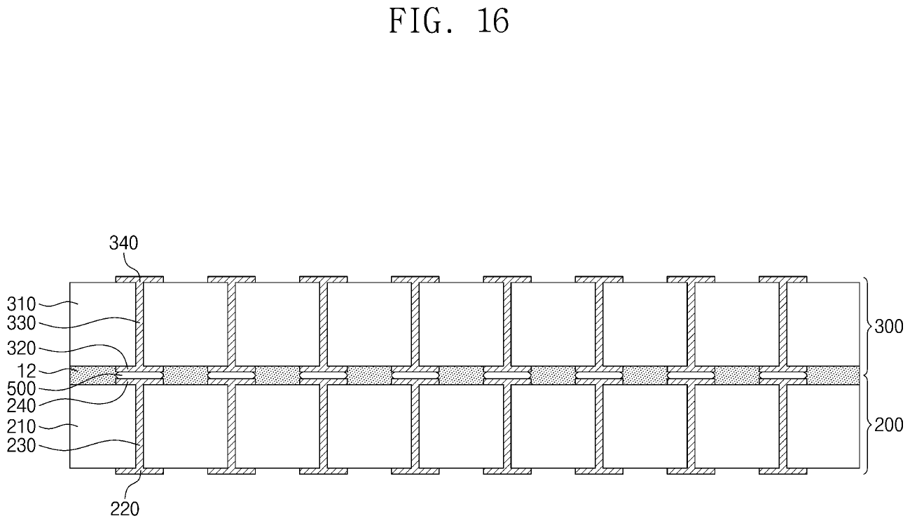

FIG. 16 is a cross-sectional view illustrating a method of fabricating a wiring substrate according to some embodiments of the present inventive concepts.

Referring to FIG. 16, on a resultant structure of FIG. 14, a first connection terminal 500 may be used to bond the first core layer 200 and the second core layer 300 together. The first connection terminal 500 may be a solder bump formed by a soldering process. The solder bump may be formed between the second core pad 240 and the third core pad 320, and thus the first core layer 200 and the second core layer 300 may be electrically connected to each other. An underfill process may be performed to form a first adhesion layer 12.

A second redistribution layer 400 may be formed on the top surface of the second core layer 300, and then a first redistribution layer 100 may be formed on a bottom surface of the first core layer 200. The first redistribution layer 100 and the second redistribution layer 400 may be formed by substantially the same or similar methods used for forming the first redistribution layer 100 and the second redistribution layer 400 discussed above in FIG. 15.

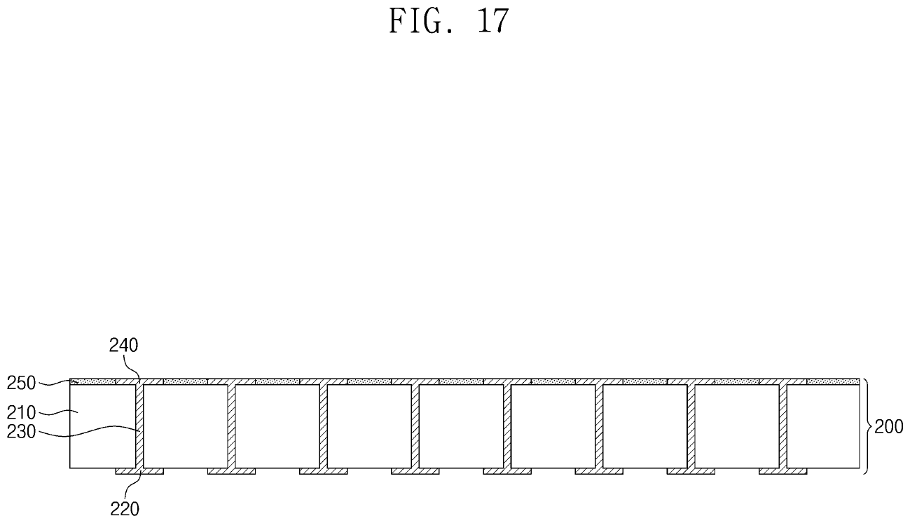

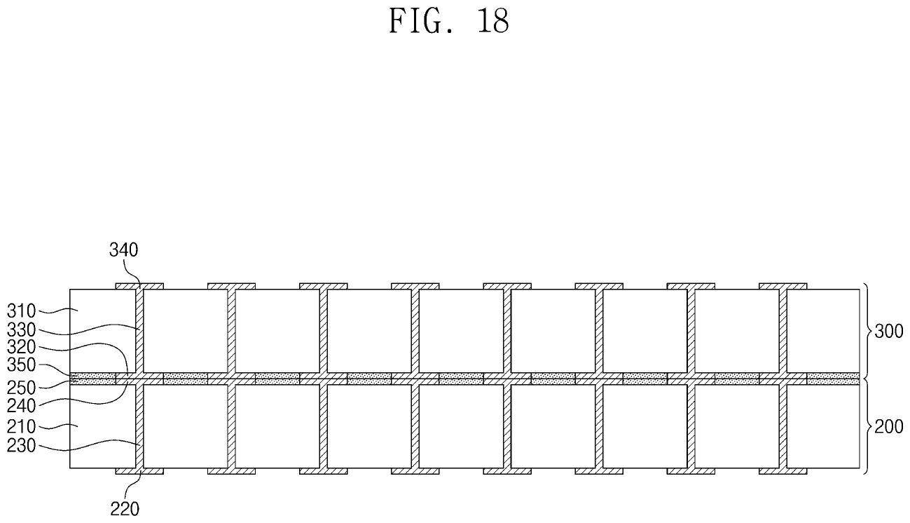

FIGS. 17 and 18 are cross-sectional views illustrating a method of fabricating a wiring substrate according to some embodiments of the present inventive concepts.

Referring to FIG. 17, on a resultant structure of FIG. 13, a dielectric material may be coated on the top surface of the first core section 210, and then exposure and development processes may be performed to additionally form a first dielectric layer 250 that at least partially surrounds the second core pad 240. The dielectric material may include a photo-imageable dielectric (PID).

Referring to FIG. 18, a second core layer 300 may be provided on the first core layer 200. The second core layer 300 may be formed by substantially the same or similar method used for forming the first core layer 200 and the first dielectric layer 250 discussed above in FIG. 17. A dielectric material may be coated on a top surface of the second core layer 300, and then exposure and development processes may be performed to additionally form a second dielectric layer 350.

The second core layer 300 may be disposed on the first core layer 200. In this step, the first dielectric layer 250 and the second dielectric layer 350 may be disposed to contact each other. An interface between the second core pad 240 and the third core pad 320 and an interface between the first dielectric layer 250 and the second dielectric layer 350 may be positioned on the same plane. The second core pad 240 and the third core pad 320 may be in direct contact with each other. For example, a top surface of the second core pad 240 touches a bottom surface of the third core pad 320. The first core layer 200 and the second core layer 300 may be electrically connected to each other.

Referring to FIGS. 7 and 8, a second redistribution layer 400 may be formed on a top surface of the second core layer 300, and then a first redistribution layer 100 may be formed on a bottom surface of the first core layer 200. The first redistribution layer 100 and the second redistribution layer 400 may be formed by substantially the same or similar methods used for forming the first redistribution layer 100 and the second redistribution layer 400 discussed above in FIG. 15.

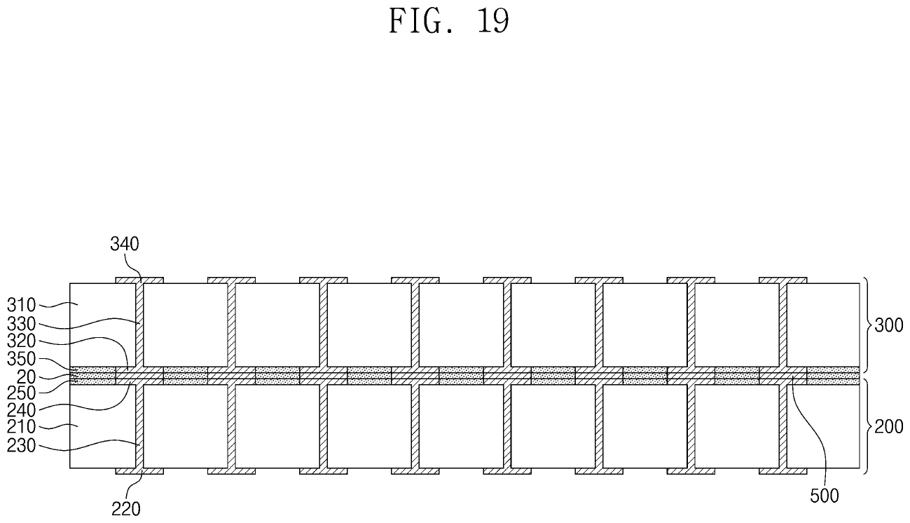

FIG. 19 is a cross-sectional view illustrating a method of fabricating a wiring substrate according to some embodiments of the present inventive concepts.

Referring to FIG. 19, on a resultant structure of FIG. 18, a first connection terminal 500 may be used to bond the first core layer 200 and the second core layer 300 together. In addition, a third dielectric layer 20 may be formed by depositing a dielectric material on the first core layer 200. The third dielectric layer 20 may be patterned to form an opening that exposes the second core pad 240, and then the opening may be filled with a conductive material to form the first connection terminal 500.

Referring to FIGS. 7 and 9, a second redistribution layer 400 may be formed on a top surface of the second core layer 300, and then a first redistribution layer 100 may be formed on a bottom surface of the first core layer 200. The first redistribution layer 100 and the second redistribution layer 400 may be formed by substantially the same or similar methods used for forming the first redistribution layer 100 and the second redistribution layer 400 discussed above in FIG. 15.

The process mentioned above may fabricate a wiring substrate and a semiconductor package including the same discussed with reference to FIGS. 13 to 19.

According to some embodiments of the present inventive concepts, a plurality of core layers may be stacked to provide a wiring substrate with increased stiffness and a semiconductor package including the same.

According to some embodiments of the present inventive concepts, a through via may be formed in each of a plurality of core layers. It may thus be possible to provide a wiring substrate which includes a through via with constant aspect ratio and increased wiring integration, and also a semiconductor package including the wiring substrate.

Although the present inventive concepts have been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not necessarily restrictive.

What is claimed is:

1. A wiring substrate, comprising:
a first redistribution layer;
a first core layer disposed on the first redistribution layer;
a second core layer disposed on the first core layer;
a first adhesion layer disposed between the first core layer and the second core layer; and
a second redistribution layer disposed on the second core layer,
wherein the first core layer includes:
a first core section; and
a first core pad disposed on a top surface of the first core section,
wherein the second core layer includes:
a second core section; and
a second core pad disposed on a bottom surface of the second core section,
wherein the first core layer and the second core layer are electrically connected to each other through the first core pad and the second core pad.

2. The wiring substrate of claim 1, further comprising:
a first through via that vertically penetrates the first core section and is electrically connected to the first core pad; and
a second through via that vertically penetrates the second core section and is electrically connected to the second core pad,
wherein the first through via is vertically aligned with the second through via.

3. The wiring substrate of claim 1, further comprising:
a first through via that vertically penetrates the first core section and is electrically connected to the first core pad; and
a second through via that vertically penetrates the second core section and is electrically connected to the second core pad,
wherein the first through via and the second through via are moved away from each other.

4. The wiring substrate of claim 1, further comprising a connection terminal disposed between the first core pad and the second core pad,
Wherein the first core pad and the second core pad are electrically connected to each other through the connection terminal.

5. The wiring substrate of claim 3, wherein
a width of the first core pad is the same as a width of the second core pad, and
the first core pad and the second core pad are moved away from each other in a direction parallel to a top surface of the first redistribution layer.

6. The wiring substrate of claim 3, wherein the first core pad overlaps a portion of the second core pad.

7. The wiring substrate of claim 1, wherein
the first core layer further includes a first dielectric layer disposed on the top surface of the first core section, wherein the first dielectric layer at least partially surrounds the first core pad,
the second core layer further includes a second dielectric layer disposed on the bottom surface of the second core section, wherein the second dielectric layer at least partially surrounds the second core pad, and
the first adhesion layer is disposed between the first dielectric layer and the second dielectric layer.

8. The wiring substrate of claim 1, further comprising:
a third core layer disposed between the second core layer and the second redistribution layer; and
a second adhesion layer disposed between the second core layer and the third core layer, wherein the second adhesion layer bonds the second core layer and the third core layer together,
the second core layer further includes a third core pad disposed on a top surface of the second core layer,
wherein the third core layer includes:
a third core section;
a fourth core pad disposed on a bottom surface of the third core section; and
a third through via that vertically penetrates the third core section and is electrically connected to the fourth core pad,
wherein the second core layer and the third core layer are electrically connected to each other through the third core pad and the fourth core pad.

9. The wiring substrate of claim 1,
wherein the first redistribution layer includes:
a first substrate dielectric pattern that covers a bottom surface of the first core layer;
a first substrate wiring pattern disposed on a bottom surface of the first substrate dielectric pattern; and
a first substrate via that vertically penetrates the first substrate dielectric pattern to connect the first substrate wiring pattern to the first core layer,
wherein the second redistribution layer includes:
a second substrate dielectric pattern that covers a bottom surface of the second core layer;
a second substrate wiring pattern disposed on a top surface of the second substrate dielectric pattern; and
a second substrate via that vertically penetrates the second substrate dielectric pattern to connect the second substrate wiring pattern to the second core layer.

10. A wiring substrate, comprising:
a first redistribution layer;
a second redistribution layer disposed on the first redistribution layer;
a first core layer disposed between the first redistribution layer and the second redistribution layer; and
a second core layer disposed between the first core layer and the second redistribution layer,
wherein the first core layer includes:
a first core section;
a first core pad disposed on a top surface of the first core section; and
a first through via that vertically penetrates the first core section and is electrically connected to the first core pad,
wherein the second core layer includes:
a second core section;
a second core pad disposed on a bottom surface of the second core section; and
a second through via that vertically penetrates the second core section and is electrically connected to the second core pad,
wherein the first core layer and the second core layer are electrically connected to each other through the first core pad and the second core pad, and
wherein the first through via and the second through via are moved away from each other.

11. The wiring substrate of claim 10, wherein an outer lateral surface of the first core pad is vertically aligned with an outer lateral surface of the second core pad.

12. The wiring substrate of claim 10, wherein the second core pad extends onto the first through via to contact the first core pad.

13. The wiring substrate of claim 10, further comprising an adhesion layer disposed between the first core layer and the second core layer, wherein the adhesion layer bonds the first core layer and the second core layer together.

14. The wiring substrate of claim 10, wherein
the first core layer further includes a first dielectric layer disposed on the top surface of the first core section, wherein the first dielectric layer at least partially surrounds the first core pad,
the second core layer further includes a second dielectric layer disposed on the bottom surface of the second core section, wherein the second dielectric layer at least partially surrounds the second core pad, and
a top surface of the first dielectric layer is in direct contact with a bottom surface of the second dielectric layer.

15. The wiring substrate of claim 14, further comprising:
A third dielectric layer disposed between the first dielectric layer and the second dielectric layer; and
a connection terminal in the third dielectric layer,
wherein the connection terminal is in direct contact with a top surface of the first core pad and a bottom surface of the second core pad.

16. A semiconductor package, comprising:
a wiring substrate;
a semiconductor chip disposed on the wiring substrate; and
a molding layer disposed on the wiring substrate while covering the semiconductor chip,
wherein the wiring substrate includes a first redistribution layer, a first core layer, a second core layer, and a second redistribution layer that are sequentially stacked,
wherein the first core layer includes:
a first core section; and
a first core pad disposed on a top surface of the first core section,
wherein the second core layer includes:
a second core section; and
a second core pad disposed on a bottom surface of the second core section,
wherein the first core pad and the second core pad are in direct contact with each other.

17. The semiconductor package of claim 16, wherein the first core pad and the second core pad constitute a single unitary piece formed of the same material.

18. The semiconductor package of claim 16, wherein
The first core layer further includes a first through via that vertically penetrates the first core section and is electrically connected to the first core pad,
the second core layer further includes a second through via that vertically penetrates the second core section and is electrically connected to the second core pad, and
the first through via and the second through via are vertically aligned with each other.

19. The semiconductor package of claim 16, wherein
the first core layer further includes a first through via that vertically penetrates the first core section and is electrically connected to the first core pad,
the second core layer further includes a second through via that vertically penetrates the second core section and is electrically connected to the second core pad, and
the first through via and the second through via are moved away from each other in a direction parallel to a top surface of the first redistribution layer.

20. The semiconductor package of claim 16, further comprising a dielectric layer disposed between the first core layer and the second core layer, wherein the dielectric layer at least partially surrounds the first core pad and the second core pad.
